(19) United States
(12) Patent Application Publication
(10) Pub. No.: US 2018/0358203 A1
(43) Pub. Date: Dec. 13, 2018

(54) MULTI CHARGED PARTICLE BEAM WRITING APPARATUS AND MULTI CHARGED PARTICLE BEAM ADJUSTING METHOD

(71) Applicant: NuFlare Technology, Inc., Yokohama-shi (JP)

(72) Inventor: Hirofumi Morita, Setagaya-ku (JP)

(73) Assignee: NuFlare Technology, Inc., Yokohama-shi (JP)

(21) Appl. No.: 15/992,451

(22) Filed: May 30, 2018

(30) Foreign Application Priority Data
Jun. 7, 2017 (JP) 2017-112753

(51) Int. Cl. H01J 37/317

(52) U.S. Cl. CPC H01J 37/3177; H01J 37/3175; H01J 2237/0437; H01J 2237/0492; H01J 2237/0432; H01J 2237/1501

(57) ABSTRACT

In one embodiment, a multi charged particle beam writing apparatus includes a shaping aperture array forming multiple beams by allowing part of a charged particle beam to pass through a plurality of first openings, a blanking aperture array having a plurality of second openings having respective blankers each configured to deflect and blank the beam passing therethrough, a stopping aperture member having a third opening and configured to block deflected beams of the multiple beams at a position off the third opening, a first alignment coil disposed between the blanking aperture array and the stopping aperture member and adjusting a beam path, an objective lens disposed between the stopping aperture member and a stage, and a movement controller controlling a movement of a position of the third opening in an in-plane direction of the stopping aperture member.

### CROSS REFERENCE TO RELATED APPLICATION

This application is based upon and claims benefit of priority from the Japanese Patent Application No. 2017-112753, filed on Jun. 7, 2017, the entire contents of which are incorporated herein by reference.

### FIELD

The present invention relates to a multi charged particle beam writing apparatus and a multi charged particle beam adjusting method.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

A writing apparatus using multiple beams can provide significantly improved throughput, because it is capable of irradiating with more beams at a time than when writing with a single electron beam. In a multi-beam writing apparatus using a blanking aperture array, which is a type of multi-beam writing apparatus, for example, an electron beam emitted from an electron gun is passed through a shaping aperture array having a plurality of holes to form multiple beams (a plurality of electron beams). The multiple beams pass through corresponding blankers in the blanking aperture array. A stopping aperture member is disposed below the blanking aperture array. The multiple beams passing through the blanking aperture array form a crossover at the position of an opening in the stopping aperture member.

The blanking aperture array has electrode pairs (blankers) each configured to individually deflect a beam, and an opening for passage of the beam is provided between electrodes. One electrode of each blanker is fixed at the ground potential and the other electrode of the blanker is switched between the ground potential and another potential, so that electron beams passing through the blankers are individually deflected and blanked. Electron beams deflected by the blankers are blocked by the stopping aperture member, whereas undeflected electron beams pass through the opening in the stopping aperture member and are applied onto a substrate (a mask).

Generally, apertures are categorized into the following types: shaping apertures (including “shaping aperture arrays”), limiting apertures (which may also be referred to as “lens apertures” or simply as “apertures”), and stopping apertures. A shaping aperture is configured to form a beam into a desired shape and is disposed at a position where the beam is greatly extended by a lens system. When irradiated with a beam, the shaping aperture allows only part of the beam corresponding to the desired shape to pass therethrough and blocks the remaining part. A lens aperture is configured to adjust a beam current or convergence state and is disposed before or after, or at substantially the same position as, the lens. The lens aperture allows a midportion of an extended beam to pass therethrough and blocks an unnecessary beam therearound. In contrast, a stopping aperture normally allows passage of the entire beam and blocks only deflected beams by blankers. In an optical system for a multi-beam writing apparatus, the stopping aperture is disposed near the image plane of a crossover (light source image) where beam extent is converged.

Blanking performed in the multi-beam writing apparatus requires high-speed operation for improved controllability over a writing dose. In terms of circuit techniques, the high-speed operation becomes difficult as the output voltage (i.e., blanker driving voltage) increases. Therefore, with currently available techniques, the output voltage can be increased only up to, for example, about 3 V to 5 V. The pitch of an individual beam in the blanker plane ranges from about 30 μm to 50 μm. Blankers are manufactured by microfabrication techniques. The longest possible length of electrodes of blankers that can be produced by currently available microfabrication techniques ranges from 20 μm to 40 μm. That is, since the voltage applied to the blankers cannot be made so high and the electrode length has limitations, it has been difficult to increase the amount of deflection made by the blankers. When the amount of deflection is limited, the beam blocking ratio is low. To compensate for this and improve controllability over a writing dose, it is preferable to reduce the opening diameter of the stopping aperture.

In the multi-beam writing apparatus, a plurality of beams are applied at a time and beams formed by passing through the same or different holes in the shaping aperture array are stitched together to write patterns of desired shapes. The shape of the entire multi-beam image projected onto the substrate has an influence on the stitching accuracy of written shapes. Therefore, it is required to accurately form a shaping aperture array image on the substrate.

In the multi-beam writing apparatus, to lessen the impact of shape error in the shaping aperture array, it is required to form an image with a high reduction ratio. This high-reduction imaging is realized by a two-stage objective lens. Thus, in the optical system of the multi-beam writing apparatus, a two-stage objective lens (first and second objective lenses) is disposed between the stopping aperture member and the substrate.

The multi-beam writing apparatus forms a large image on the substrate surface. This means that even when the beam path is only slightly displaced from the lens center, the entire multi-beam image is distorted significantly. To reduce such distortion, a beam passing through the opening in the stopping aperture member needs to pass through the center of the two-stage objective lens. However, since mechanical error causes an axial displacement between the objective lenses, or between an objective lens and the stopping aperture member, it has been difficult to allow the beam passing through the opening in the stopping aperture member to pass through the center of the two-stage objective lens.

As described above, to improve the beam blocking ratio during blanking, the stopping aperture preferably has a small opening diameter. However, when the opening diameter of the stopping aperture is reduced, it is more difficult to allow a beam passing through the opening in the stopping aperture member to pass through the center of the two-stage objective lens.

An alignment coil may be provided between the stopping aperture member and the first objective lens to deflect the beam path. In optical design practice, however, it is difficult to place the alignment coil because the stopping aperture member and the first objective lens are arranged close to each other.

### BRIEF DESCRIPTION OF THE DRAWINGS

FIG. 1 is an overall view of a multi charged particle beam writing apparatus according to an embodiment of the present invention.

FIG. 2 is a schematic diagram of a shaping aperture array.

FIG. 3A is a schematic diagram illustrating a beam path observed before positioning of a stopping aperture member, and FIG. 3B is a schematic diagram illustrating a beam path observed after positioning of the stopping aperture member.

FIG. 4 is a flowchart illustrating a method for determining the position of the stopping aperture member.

### DETAILED DESCRIPTION

In one embodiment, a multi charged particle beam writing apparatus includes an emitter emitting a charged particle beam, a shaping aperture array having a plurality of first openings, irradiated with the charged particle beam in a region including the plurality of first openings, and forming multiple beams by allowing part of the charged particle beam to pass through the plurality of first openings, a blanking aperture array having a plurality of second openings each configured to allow a corresponding beam of multiple beams passing through the plurality of first openings to pass therethrough, the plurality of second openings having respective blankers each configured to deflect and blank the beam passing therethrough, a stopping aperture member having a third opening and configured to block deflected beams of the multiple beams at a position off the third opening, the deflected beams being deflected by the blankers in such a manner as to be turned off, the stopping aperture member being configured to allow beams in an on-state to pass through the third opening, a first alignment coil disposed between the blanking aperture array and the stopping aperture member and adjusting a beam path, an objective lens disposed between the stopping aperture member and a stage configured to hold thereon a substrate subjected to writing with the beams, and a movement controller controlling a movement of a position of the third opening in an in-plane direction of the stopping aperture member.

Hereinafter, an embodiment of the present invention will be described on the basis of the drawings. The embodiment deals with a configuration where electron beams are used as charged particle beams. Note that the charged particle beams are not limited to electron beams and may be, for example, ion beams.

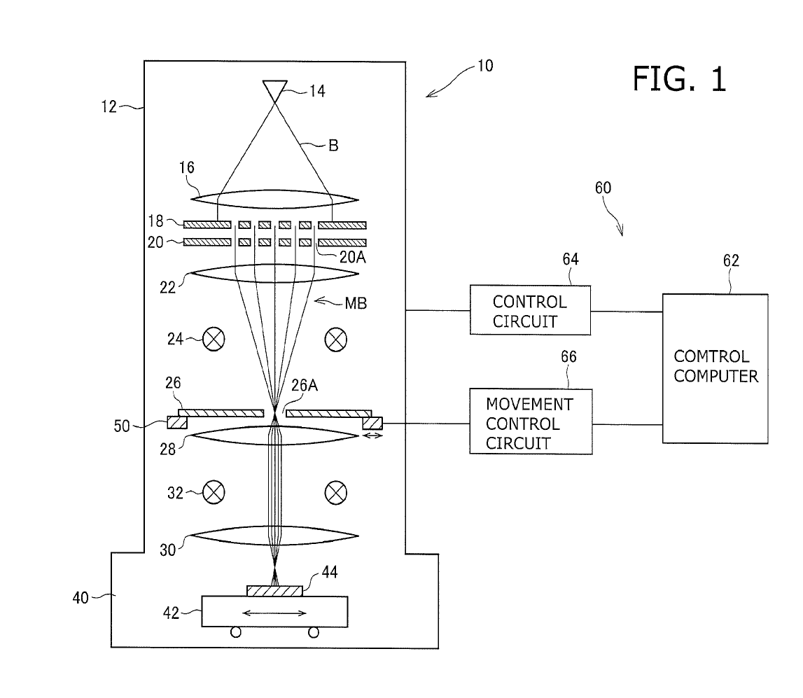

A writing apparatus illustrated in FIG. 1 includes a writer 10 configured to irradiate with electron beams a target object, such as a mask or wafer, to write a desired pattern thereon, and a controller 60 configured to control the operation of the writer 10. The writer 10 is an example of multi-beam writing device that includes an electron optical column 12 and a writing chamber 40.

The electron optical column 12 includes therein an electron gun 14, an illuminating lens 16, a shaping aperture array 18, a blanking aperture array 20, a projection lens 22, a first alignment coil 24, a stopping aperture member (limiting aperture member) 26, a first objective lens 28, a second objective lens 30, and a second alignment coil 32. An XY stage 42 is disposed in the writing chamber 40. A mask blank, which is a substrate 44 (writing target), is placed on the XY stage 42.

The target substrate 44 as a drawing target includes, for instance, a wafer and a mask for exposure which prints a pattern on a wafer using a reduced projection exposure device such as a stepper and a scanner utilizing an excimer laser as a light source, or an extreme ultraviolet ray exposure device. In addition, the drawing target substrate 44 includes a mask in which a pattern is already formed. For instance, a Levenson-type mask needs to be drawn twice, thus a second pattern may be drawn on a mask which has been drawn once and processed.

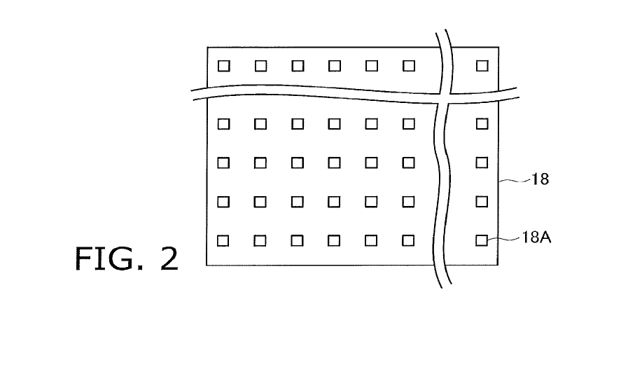

As illustrated in FIG. 2, the shaping aperture array 18 includes an m-column by n-row array of openings (first openings) 18A formed at a predetermined array pitch, where m and n are both greater than or equal to 2 (m, n≥2). All the openings 18A are rectangular openings of the same shape and dimensions. The openings 18A may be circular in shape. Multiple beams MB are formed by allowing part of an electron beam B to pass through the plurality of openings 18A.

The blanking aperture array 20 is disposed below the shaping aperture array 18 and has pass holes 20A (second openings) corresponding to the respective openings 18A in the shaping aperture array 18. The pass holes 20A are each provided with a blanker (not shown) composed of a pair of two electrodes. One of the electrodes of the blanker is fixed to the ground potential, and the other electrode is switched between the ground potential and another potential. An electron beam passing through each of the pass holes 20A is independently deflected by a voltage applied to the blanker. Thus, a plurality of blankers each deflect and blank a corresponding one of the multiple beams MB passing through the plurality of openings 18A in the shaping aperture array 18.

The stopping aperture member 26 blocks beams deflected by the blankers. Beams not deflected by the blankers pass through an opening 26A (third opening) formed in the center of the stopping aperture member 26. To reduce beam leakage during individual blanking performed by the blanking aperture array 20, the stopping aperture member 26 is disposed in the image plane of a crossover (light source image) where beam extent is converged.

The stopping aperture member 26 is mounted on a moving mechanism 50, which includes an actuator such as a motor, movable in a plane orthogonal to the direction of beam travel (beam axis direction). The moving mechanism 50 moves the stopping aperture member 26 in the direction of the aperture plane (horizontal plane), thereby adjusting the position of the opening 26A (third opening). The moving mechanism 50 used here may be, for example, one that is driven by a known piezoelectric element.

The controller 60 includes a control computer 62, a control circuit 64, and a movement control circuit 66. The movement control circuit 66 is connected to the moving mechanism 50, and the movement control circuit 66 and moving mechanism 50 constitute a movement controller.

The electron beam B emitted from the electron gun 14 (emitting unit) substantially perpendicularly illuminates the entire shaping aperture array 18 through the illuminating lens 16. The electron beam B is formed into a plurality of electron beams (multiple beams) MB by passing through the plurality of openings 18A in the shaping aperture array 18. The multiple beams MB pass through corresponding ones of the blankers in the blanking aperture array 20.

The multiple beams MB passing through the blanking aperture array 20 are reduced in size by the projection lens 22 and travel toward the opening 26A in the center of the stopping aperture member 26. Electron beams deflected by the blankers in the blanking aperture array 20 are displaced from the opening 26A in the stopping aperture member 26 and blocked by the stopping aperture member 26. On the other hand, electron beams not deflected by the blankers pass through the opening 26A in the stopping aperture member 26. Blanking control is performed by turning on and off the blankers and this controls the “on” and “off” of the beams.

As described above, the stopping aperture member 26 blocks the beams that are deflected by the blankers in the blanking aperture array 20 in such a manner as to be turned off. Beams passing through the stopping aperture member 26 during the period from “beam-on” to “beam-off” are equivalent to a single shot.

The first alignment coil 24 for adjustment of a beam path is disposed between the projection lens 22 and the stopping aperture member 26.

The multiple beams MB passing through the stopping aperture member 26 are brought into focus by the first objective lens 28 and the second objective lens 30 to form a pattern image with a desired reduction ratio, and projected onto the substrate 44. Using a two-stage objective lens, which includes the first objective lens 28 and the second objective lens 30, makes it possible to achieve a high reduction ratio. To reduce lens imaging aberrations and distortions, the stopping aperture member 26 is disposed close to, and directly above, the first objective lens 28 on the first stage (upper stage).

The second alignment coil 32 disposed between the first objective lens 28 and the second objective lens 30 adjusts the beam path in such a manner as to allow the beam to pass through the center of the second objective lens 30.

The control computer 62 reads writing data from a storage device, and performs multiple stages of data conversion to generate shot data that is specific to the apparatus. The shot data defines, for example, the amount of irradiation by each shot and the coordinates of the irradiation position of the shot.

On the basis of the shot data, the control computer 62 outputs the amount of irradiation by each shot to the control circuit 64. The control circuit 64 determines irradiation time t by dividing the input amount of irradiation by a current density. Then, when performing the corresponding shot, the control circuit 64 applies a deflection voltage to the corresponding blanker in the blanking aperture array 20 in such a manner that the beam is “on” during the irradiation time t.

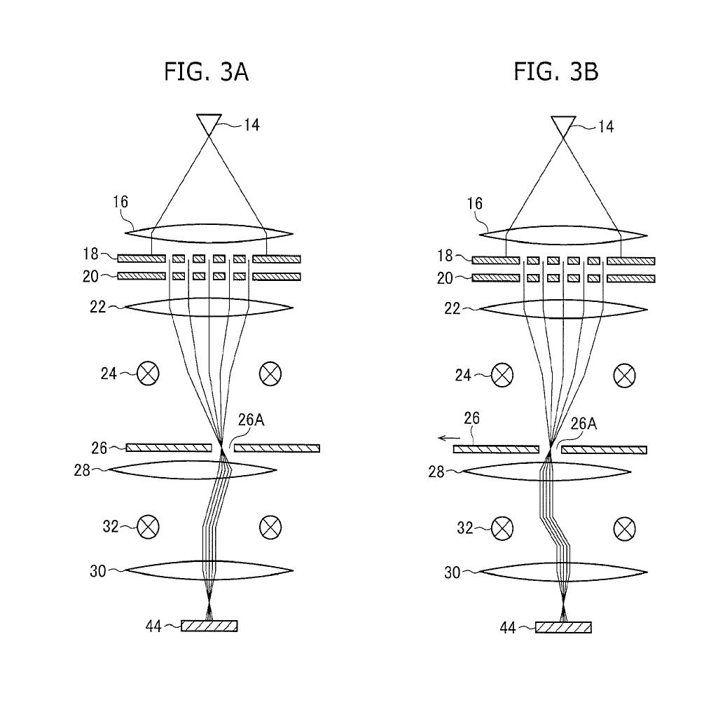

In the writer 10, for example, errors in manufacture of components or errors in installation of components to the apparatus may cause a displacement between the position of the opening 26A in the stopping aperture member 26 and the center position of the first objective lens 28. In the event of such a positional displacement, it is difficult to adjust the beam path, with the first alignment coil 24, in such a manner as to allow the beam to pass through the opening 26A in the stopping aperture member 26 and also through the center of the first objective lens 28. As a result, as illustrated in FIG. 3A, the beam path is displaced from the center of the first objective lens 28 and this causes distortion of the entire multi-beam image projected onto the substrate 44.

In the present embodiment, where the stopping aperture member 26 is mounted on the moving mechanism 50, the position of the opening 26A is adjusted in the in-plane direction of the stopping aperture member 26. By moving the stopping aperture member 26 as illustrated in FIG. 3B, it is possible to adjust the beam path, with the first alignment coil 24, in such a manner as to allow the beam to pass through the opening 26A and also through the center of the first objective lens 28. Note that the moving mechanism 50 is not shown in FIGS. 3A and 3B.

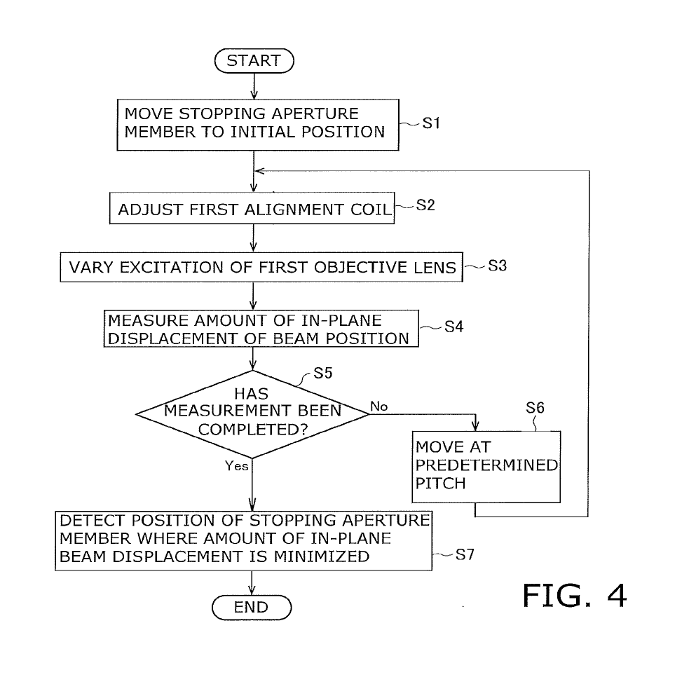

With reference to the flowchart of FIG. 4, a method for determining the position of the stopping aperture member 26 will be described.

The stopping aperture member 26 is moved to an initial position within its moving region (step S1). The moving region is several times as large as an expected mechanical error. For example, the moving region is a 500-μm by 500-μm square region.

A current in the first alignment coil 24 is adjusted in such a manner as to allow a beam to pass through the center of the opening 26A in the stopping aperture member 26 (step S2).

The excitation of the first objective lens 28 is varied, and the amount of in-plane displacement of the beam position on the substrate surface with respect to a unit amount of the variation is measured (steps S3 and S4).

If the measurement in the moving region has not been completed (NO in step S5), the stopping aperture member 26 is moved at a predetermined pitch (step S6), and steps S2 to S4 are performed again to measure the amount of beam displacement. The predetermined pitch is a distance obtained, for example, by dividing the moving region into about 5 to 20, that is, about 25 μm to 100 μm.

After the measurement of the amount of beam displacement is completed throughout the moving region (YES in step S5), the position of the opening 26A in the stopping aperture member 26 where the amount of beam displacement is minimized is detected (step S7). By positioning the opening 26A of the stopping aperture member 26 at the detected position, the first alignment coil 24 can adjust the beam path in such a manner that the beam passing through the opening 26A passes through the center of the first objective lens 28.

After the position of the opening 26A in the stopping aperture member 26 is determined, the second alignment coil 32 is adjusted in such a manner as to allow the beam to pass through the center of the second objective lens 30. For example, the excitation of the second objective lens 30 is varied, and the amount of current in the second alignment coil 32 is adjusted in such a manner as to eliminate (or minimize) the in-plane displacement of the beam position on the substrate surface with respect to the variation.

The control computer 62 outputs, to the movement control circuit 66, positional information that represents the position detected in step S7. The movement control circuit 66 controls the moving mechanism 50 in such a manner as to move the stopping aperture member 26 to the detected position. In accordance with a control signal from the control computer 62, the control circuit 64 controls the amount of current in the first alignment coil 24 and the second alignment coil 32.

By thus adjusting the position of the opening 26A in the stopping aperture member 26, the beam passing through the opening 26A in the stopping aperture member 26 can pass through the center of each of the two objective lenses 28 and 30.

In the present embodiment, even when the diameter of the opening 26A in the stopping aperture member 26 is reduced, the beam can still pass through the center of each of the two objective lenses 28 and 30. This makes it possible to produce multiple beams that are distortion-free. Additionally, since it is possible to increase the beam blocking ratio of individual blanking performed by the blanking aperture array 20 and reduce the beam blocking time, controllability over a writing dose is improved. This improves writing accuracy.

In the embodiment described above, if the amount of beam displacement at the position detected in step S7 in the flowchart of FIG. 4 is greater than a predetermined threshold, a smaller moving region centered on the detected position may be defined and steps S2 to S4 may be performed again at a narrower moving pitch. If the amount of beam displacement is smaller than the predetermined threshold, the process proceeds to the step of adjusting the second alignment coil 32.

In the embodiment described above, a plurality of the first alignment coils 24 and a plurality of the second alignment coils 32 may be provided.

The embodiment has described an example in which the moving mechanism 50 moves the stopping aperture member 26 in the in-plane direction to adjust the in-plane position of the opening 26A. Alternatively, the position of the stopping aperture member 26 may be fixed and the first objective lens 28 may be moved. Moving the stopping aperture member 26 is easier, however, because objective lenses of magnetic field type are large in size and weight and objective lenses of electrostatic type require application of a high voltage.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi charged particle beam writing apparatus comprising:
an emitter emitting a charged particle beam;
a shaping aperture array having a plurality of first openings, irradiated with the charged particle beam in a region including the plurality of first openings, and forming multiple beams by allowing part of the charged particle beam to pass through the plurality of first openings;
a blanking aperture array having a plurality of second openings each configured to allow a corresponding beam of multiple beams passing through the plurality of first openings to pass therethrough, the plurality of second openings having respective blankers each configured to deflect the beam passing therethrough;
a stopping aperture member having a third opening and configured to block deflected beams of the multiple beams at a position off the third opening, the deflected beams being deflected by the blankers in such a manner as to be turned off, the stopping aperture member being configured to allow beams in an on-state to pass through the third opening;
a first alignment coil disposed between the blanking aperture array and the stopping aperture member and adjusting a beam path;
an objective lens disposed between the stopping aperture member and a stage configured to hold thereon a substrate subjected to writing with the beams; and
a movement controller controlling a movement of a position of the third opening in an in-plane direction of the stopping aperture member.

2. The apparatus according to claim 1, wherein the objective lens includes a first objective lens and a second objective lens,
the apparatus further comprising a second alignment coil disposed between the first objective lens and the second objective lens and adjusting a path of beams passing through the second objective lens.

3. The apparatus according to claim 2, wherein the movement controller adjusts the position of the third opening in such a manner that the beams subjected to the beam path adjustment by the first alignment coil and passing through the third opening pass through a center of the first objective lens.

4. A multi charged particle beam adjusting method comprising:
emitting a charged particle beam;
forming multiple beams by using a shaping aperture array having a plurality of first openings, being irradiated with the charged particle beam in a region including the plurality of first openings, and allowing part of the charged particle beam to pass through the plurality of first openings;
measuring an amount of in-plane displacement of a beam position by varying excitation of an objective lens configured to adjust a path of the multiple beams, the multiple beams passing through a plurality of second openings in a blanking aperture array and a third opening in a stopping aperture member placed at an initial position; and
adjusting a beam path in such a manner that by moving the third opening to a position where the amount of in-plane displacement of the beam position is minimized, the beams passing through the third opening pass through a center of the objective lens.

5. The method according to claim 4, wherein the objective lens includes a first objective lens and a second objective lens;
the stopping aperture member is moved to a position that allows the beams passing through the third opening to pass through a center of the first objective lens; and
the beam path is adjusted in such a manner that the beams passing through the first objective lens pass through a center of the second objective lens.

6. The method according to claim 5, wherein excitation of the first objective lens is varied, and the stopping aperture member is moved in such a manner as to minimize the amount of in-plane displacement of the beam position.

7. The method according to claim 5, wherein excitation of the second objective lens is varied, and the amount of current in an alignment coil disposed between the first objective lens and the second objective lens is adjusted in such a manner as to minimize the amount of in-plane displacement of the beam position.
